(19) United States
(12) Patent Application Publication
(10) Pub. No.: US 2005/0224904 A1
(43) Pub. Date: Oct. 13, 2005

(54) Solar battery and clothes

(76) Inventors: Yasuhiko Kasama, Sendai-Shi (JP); Satoshi Fujimoto, Sendai-Shi (JP); Kenji Omote, Sendai-Shi (JP)

Correspondence Address: YOUNG & THOMPSON, 745 SOUTH 23RD STREET, 2ND FLOOR, ARLINGTON, VA, 22202, US

(21) Appl. No.: 10/513,143

(22) PCT Filed: May 2, 2003
(86) PCT No.: PCT/JP03/05622

§ 371 Date: May 6, 2005

(30) Foreign Application Priority Data
May 2, 2002 (JP) 2002-131013

(51) Int. Cl. H01L 31/00

(52) U.S. Cl. 257/458; 257/459

(57) ABSTRACT

A solar battery which is not limited by shape but has plasticity or flexibility and is capable of being formed into an optional shape and whose degree of integration is extremely high is provided. A plurality of line elements in which a cross section having a photoelectromotive force circuit element is formed continuously or intermittently in the longitudinal direction are bundled, twisted, woven, joined, formed in combination or formed in the non-woven state.

### FIELD OF THE INVENTION

The present invention relates to a solar battery using a line element.

### BACKGROUND ART

Nowadays, various types of devices using integrated circuits have prevailed in a wide range, and efforts are being made for further high integration and densification. One of those efforts is a three-dimensional integration technique.

Any of those devices, however, has a basic constitution of rigid boards such as wafers. Due to such a basic constitution with the rigid boards, its manufacturing method is restrained, and a degree of integration has a limitation. Moreover, the shape of devices is limited.

Also, electrically conductive fibers in which the surface of cotton or silk is plated or surrounded by an electrically conductive material such as gold or copper are known.

However, such a technique that a circuit element is formed in a single filament is not known. Also, even though it is an electrically conductive fiber, the filament itself is basically constituted with cotton or silk, and the filament itself is provided at its center.

The present invention has an object to provide a solar battery which is not limited by the shape but has high integration and plasticity or flexibility and is formable in an optional shape and its manufacturing method.

### DESCRIPTION OF THE INVENTION

The present invention is a solar battery characterized by that a plurality of line elements in which a photoelectromotive force circuit element is formed continuously or intermittently in the longitudinal direction are bundled, twisted, woven or knitted, joined, formed in combination or formed in the non-woven state.

The present invention is a solar device characterized by that a plurality of line elements in which a cross section having a plurality of areas forming a photoelectromotive force circuit is formed continuously or intermittently in the longitudinal direction are bundled, twisted, woven or knitted, joined, formed in combination or formed in the non-woven state.

The present invention is a fabric-state body characterized by being formed by weaving or knitting a plurality of line elements in which a photoelectromotive force circuit element is formed continuously or intermittently in the longitudinal direction.

The present invention is a fabric-state body characterized by being formed by weaving or knitting a plurality of line elements in which a cross section having a plurality of areas forming a photoelectromotive force circuit is formed continuously or intermittently in the longitudinal direction.

The present invention is clothes characterized by production by weaving or knitting a plurality of line elements in which a cross section having a plurality of areas forming a photoelectromotive force circuit is formed continuously or intermittently in the longitudinal direction.

The present invention is clothes characterized by production by weaving or knitting a plurality of line elements in which a cross section having a plurality of areas forming a photoelectromotive force circuit is formed continuously or intermittently in the longitudinal direction.

The outer diameter of the line element in the present invention is preferably 10 mm or less and more preferably, 5 mm or less. 1 mm or less is more preferable, and 10 μm or less is furthermore preferable. It is possible to make it 1 μm or less or further 0.1 μm or less by applying drawing processing. In order to weave the line element into a fabric state, it is more preferable if the outer diameter is smaller.

If a super-fine filament with the outer diameter of 1 μm or less is to be discharged from a hole of a mold for formation, there can be clogging of the hole or breakage of the filament. In these cases, a linear object of each area is formed first. Then, supposing this linear object as an island, and many islands are formed, and their periphery (sea) is surrounded by a soluble object. And they are bundled by a funnel shaped mouthpiece and made to discharge as a single linear object from a small mouth. By increasing the island component to make the sea component small, an extremely fine line element can be made.

As another method, a thick line element is made once and then, drawn in the longitudinal direction. Also, it is possible to realize super fineness by loading a fused material on a jet stream for melt blow.

An aspect ratio can take an optional value by extrusion. In the case of spinning, 1000 or more is preferable. 100000 or more is possible, for example. In the case of use after cutting, it can be a small unit of line element of 10 to 10000, 10 or less, 1 or less or further 0.1 or less.

(Cross Sectional Shape)

The cross sectional shape of the line element is not particularly limited. It can be a circle, polygon, star, crescent, petal or any other shapes, for example. It can be a polygon with plural vertical angles which are acute.

Also, the cross section of each area can be optional. That is, in the case of a structure shown in FIG. 1, for example, a gate electrode may be in the shape of a star, while the outer shape of the line element can be circular. If a contact surface with the adjacent layer is to be made large depending on the element, it is preferable to have a polygon shape with acute vertex angles.

A desired shape of the cross section can be easily realized by having the desired shape of an extrusion die.

If the cross section of the outermost layer is in the shape of a star or a shape with acute vertex angles, another optional material can be embedded by dipping into a space between the vertex angles after extrusion, for example, and the characteristics of the element can be changed depending on application of the element.

Also, by engaging a line element with the recess shaped cross section with a line element with the projecting shaped cross section, connection between line elements can be made effectively.

If doping of impurities into a semiconductor layer is desired, the impurities can be contained in a fusion material, but it is possible to pass it through a vacuum chamber in the line state after extrusion and dope the impurities in the vacuum chamber by ion implantation, for example. If the semiconductor layer is formed not on the outermost layer but inside, ion can be implanted only into the semiconductor layer, which is an inner layer, by controlling ion radiation energy.

(Manufacture Example, Post-Processing Formation)

The above manufacture example is an example of integral forming of an element having a plurality of layers by extrusion, but it can be also formed by forming a base part of the element in the line state by extrusion and coating the base part after that by an appropriate method.

(Raw Material)

As a material for the electrode, semiconductor layers, etc., it is preferable to use an electrically conductive polymer. They can be polyacetylene, polyacene, (oligo acene), polythiazyl, polytiophene, poly (3-alkyl tiophene), oligo tiophene, poly pyrrole, polyaniline, polyphenylene, etc. An electrode or a semiconductor layer may be selected from them, considering conductivity and so on.

As a material for semiconductor, polyparaphenylene, polytiophene, poly (3-methyltiophene) are used suitably.

Also, as a source/drain material, those with dopant mixed in the above semiconductor material can be used. To have n-type, alkali metal (Na, K, Ca) may be mixed. AsF₅/AsF₃ or ClO₄⁻ is used as a dopant in some cases.

As an insulating material, a general resin material can be used. Also, an inorganic material such as SiO₂ can be used.

In the case of a line element in the structure having a semiconductor area or an electrically conductive area at the center, the center area can be constituted by an amorphous material (metal material such as aluminum, copper, etc.; semiconductor material such as silicone). A line-state amorphous material is inserted into the stop part of a die to make the line-state amorphous material run, and its outer circumference can be coated by the other desired areas by injection.

### BRIEF DESCRIPTION OF THE DRAWINGS

FIG. 1 is a cross-sectional view showing a line element used in a solar battery constitution according to a preferred embodiment.

FIG. 2 is a conceptual front view showing a manufacturing device example of the line element.

FIG. 3 is a front view showing an extruding device used for manufacture of the line element and a plan view of a die.

FIG. 4 is a view showing a manufacture process example of the line element.

FIG. 5 is a view showing a manufacture example of the line element.

FIG. 6 is a process diagram showing a manufacture example of the line element.

FIG. 7 is a perspective view showing a manufacture example of the line element.

### BEST MODE FOR CARRYING-OUT OF THE INVENTION

### EXAMPLE 1

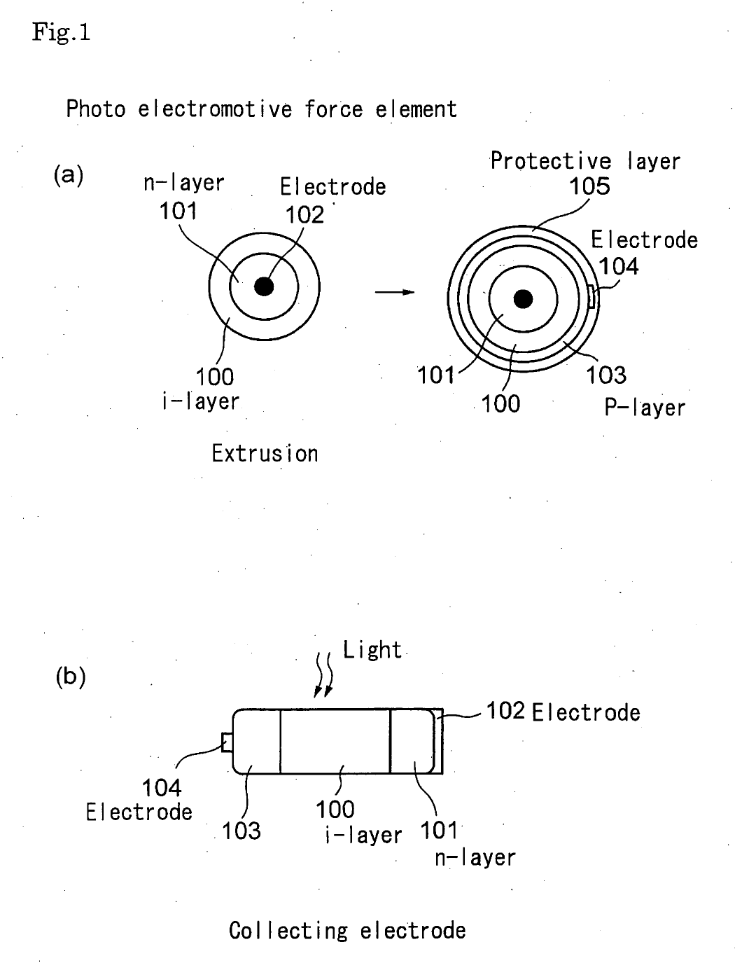

FIG. 1(a) shows a line element.

This example is a line element having a pin structure.

That is, an electrode area 102 is provided at the center, and on its outside, an n-layer area 101, an i-layer area 100, a p-layer area 103, an electrode area 104 are formed. In this example, a protective layer area 105 comprised of a transparent resin or the like is provided on the outside of the p-layer area 103.

This line element is integrally formed by extruding the electrode area 102, the n-layer area 101 and the i-layer area 100.

The p-layer area 103 and the electrode area 104 are formed by post-application processing such as coating, for example. By using post-application processing for the p-layer area 103, the thickness of the p-layer area 103 can be reduced. Therefore, if used as a photoelectromotive force element, it becomes possible to take in incident light from the p-layer 103 efficiently into a depletion layer.

Of course, the electrode area 102, the n-layer area 101, the i-layer area 100, the p-layer area 103 and the electrode area 104 may be integrally formed by extrusion.

In FIG. 1(a), the circumferential shape of the i-layer is circular, but it is preferable to have the star shaped. By this, the mating area between the p-layer 103 and the i-layer 100 is increased, whereby the conversion efficiency can be improved.

In the example shown in FIG. 1(a), the electrode 104 is provided at a part of the p-layer 103, but it can be formed covering the overall length.

In the case of the pn structure, a p⁺-layer may be provided between the p-layer 103 and the electrode 104. By providing a p⁺-layer, ohmic contact between the p-layer 103 and the electrode 104 becomes easy. Also, electrons tend to flow to the i-layer side more easily.

As the semiconductor material to form the p-layer, the n-layer and the i-layer, an organic semiconductor material is used suitably. polytiophene, polypyrrol and so on are used, for example. To have the p-type and the n-type, doping may be used as appropriate. Combination of p-type polypyrrole/n-type polytiophene can be used, too.

The electrically conductive polymer is preferable also as the electrode material.

### EXAMPLE 2

FIG. 1(b) shows the line element of another constitution.

In the above example, the pin structure was formed concentrically, but in this example, it has a rectangular cross section. A p-layer area 83, an i-layer area 80 and an n-layer area 81 are arranged horizontally. Also, electrodes 82, 83 are formed on the side, respectively.

In this example, the cross section shown in FIG. 1(b) is formed continuously in the longitudinal direction.

The line element in this structure can be formed integrally by extrusion.

### EXAMPLE 3

In this example, an electrode area is provided at the center, and an area made of a material in which a p-type material and an n-type material are mixed is formed on its outer circumference. Further on its outer circumference, the electrode area is formed.

That is, in the above example, a diode element in the double-layered structure in which the p-layer is joined with the n-layer (or a three-layered structure with an i-layer interposed) is shown. However, this example is an example of a single-layered structure comprised of a material in which the p-type material is mixed with the n-type material.

The p-type/n-type mixed material can be obtained by mixing an electron-donating conductive polymer and an electron accepting conductive polymer.

When the element area is formed by the p-type/n-type mixed material, a simple structure can be obtained, which is preferable.

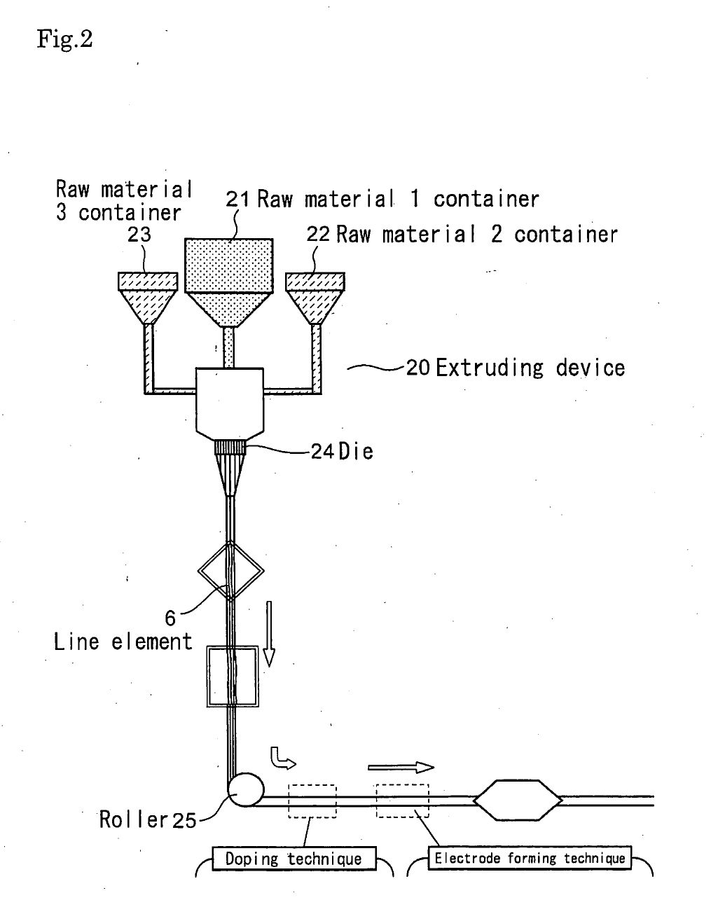

FIG. 2 shows a general constitution of an extruding device for forming such a line element.

An extruding device 20 has raw material containers 21, 22 and 23 for holding a material for constituting a plurality of areas in the melted state, fused state or gel state. In the example shown in FIG. 2, three raw material containers are shown, but they can be provided as appropriate according to the constitution of the line element to be manufactured.

The raw material in the raw material container 23 is fed to a die 24. In the die 24, injection holes according to the cross section of the line element to be manufactured are formed. Linear objects injected from the injection holes are wound around a roller 25 or fed in the line state to the next process when necessary.

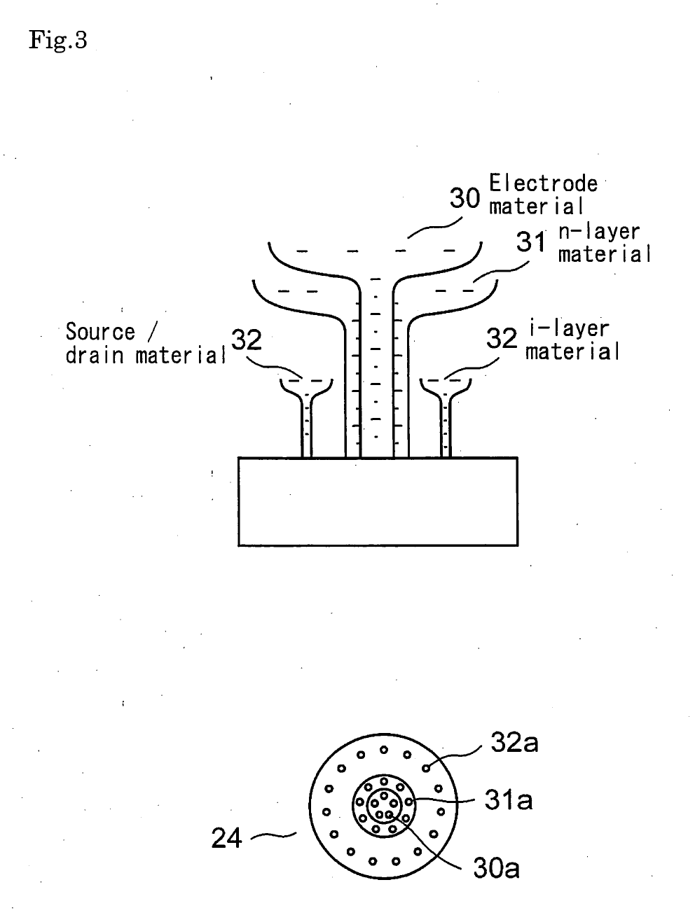

In the case of manufacture of the line element in the structure shown in FIG. 1, a constitution shown in FIG. 3 is used.

In the raw material containers, an electrode material 30, a n-layer material 31 and an i-layer material 32 are held in the respective containers in the melted, fused or gel state. In the meantime, in the die 24, holes are formed in communication with the respective material containers.

That is, at the center part, a plurality of holes 30a for injecting the electrode material 30 are formed. On its outer periphery, a plurality of holes 31a for injecting the n-layer material 31 are formed. And further on its outer periphery, a plurality of holes 32a for injecting the i-layer material are formed.

From each of the raw material containers, the raw material in the melted, fused or gel state is fed to the die 24, and when the raw material is injected, the raw material is injected from each of the holes and solidified. By pulling its end, the line element can be formed continuously in the filament state.

The filament-state line element is wound around the roller 25. Or, it is fed in the filament state to the next process when necessary.

As an electrode material, an electrically conductive polymer may be used. For example, polyacetylene, polyphenylene vinylene, polypyrrole, etc. are used. Especially, it is preferable to use polyacetylene, since a line element with smaller outer diameter can be formed.

As an i-layer material, polyparaphenylene, polytiophene, poly (3-methyltiophene), for example, are used suitably.

As an n-layer material, those with dopant mixed may be used. To have an n-type, alkali metal (Na, K, Ca), for example, may be mixed. AsF₅/AsF₃ or ClO₄⁻ is used as a dopant in some cases.

The materials cited above are also used for the line element shown in the following examples.

In this example, a discharge electrode is connected to the end face of the line element. It is needless to say that a discharge port can be provided on the side at an appropriate location in the longitudinal direction.

### EXAMPLE 4

This example shows an example to sequentially form each area in the line element shown in FIG. 1.

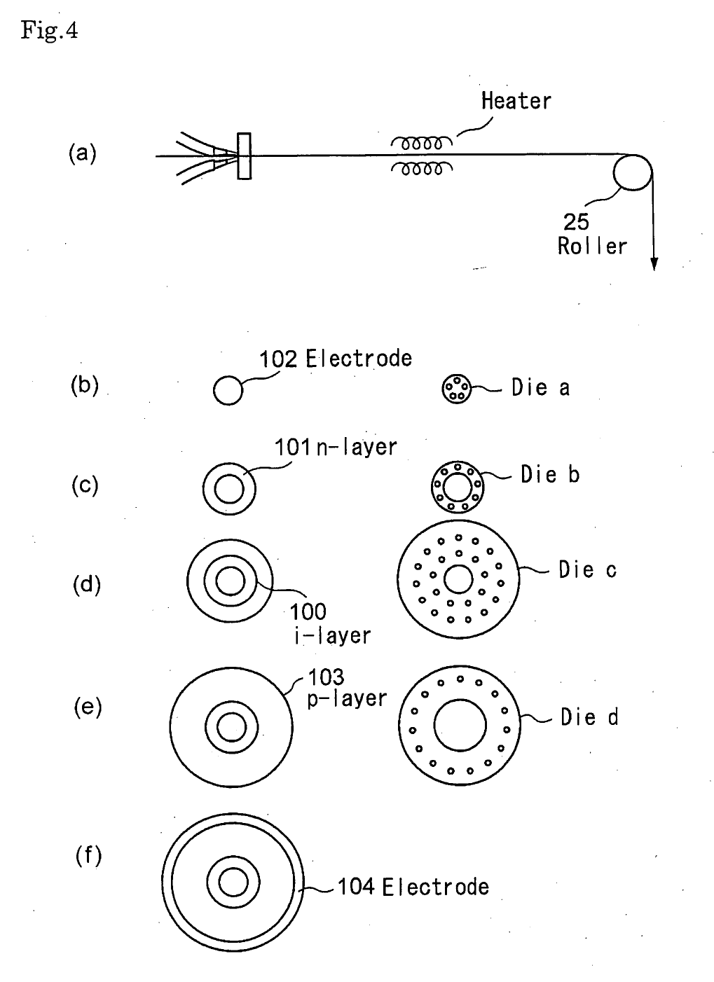

The procedure is shown in FIG. 4.

First, by a spinning technique, an electrode material is injected from the hole of a die a so as to form the electrode 102 (FIG. 4(b)). This electrode 102 is called as an intermediate filament for convenience.

Then, as shown in FIG. 4(a), the intermediate filament is inserted through the center of a die b, and while having the intermediate filament run, the insulating film material is injected from a hole formed in the die b so as to form the n-layer 101 (FIG. 4(C)). A heater is provided on the downstream side of the die b. The filament is heated by this heater as necessary. By heating, it becomes possible to remove a solvent component in the insulating film from the insulating film. It also applies to the following formation of the i-layer and p-layer.

Then, while having the intermediate filament run, the i-layer 100, p-layer 104, electrode 104 are formed (FIG. 4(c), (d), (e)).

### EXAMPLE 5

FIG. 4 shows another example 6.

This example is an injection example of an electrically conductive polymer when the electrically conductive polymer is used as a forming material of a semiconductor element.

The above example shows an example to form an outer layer on the surface of the intermediate filament while inserting the intermediate filament through the die. This example shows a case where this outer layer is the electrically conductive polymer.

A raw material 82V₁-V₀ is 20 m/sec or more. Preferably, it is 50 m/sec. More preferably, it is 100 m/sec or more. An upper limit is a speed at which the intermediate filament is not cut. The speed at which cutting occurs depends on a discharge amount of a material, viscosity of a material, an injection temperature, etc., but to be concrete, it is only necessary to acquire it in advance by experiments by setting conditions such as materials to be used.

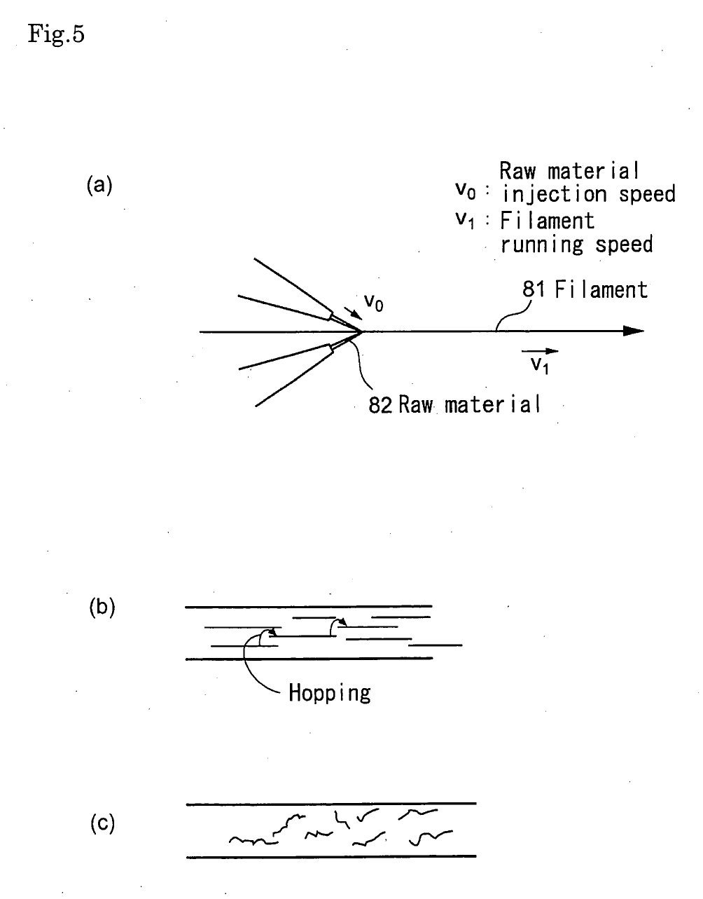

To a material injected by setting the injection speed V₀ and the running speed V₁ at 20 m/sec or more, acceleration and an external force are applied. A main direction of the external force is the running direction. A molecular chain in the electrically conductive polymer is usually in the twisted state as shown in FIG. 5(c), and its longitudinal direction is at random. However, when the external force is applied in the running direction together with the injection, the molecular chain is untwisted as shown in FIG. 5(b) but is oriented horizontally in the longitudinal direction.

Electron (or hole) moves, as shown in FIG. 5(b), by hopping to a molecular chain at the closest level. Thus, when the molecular chain is oriented in the horizontal direction as shown in FIG. 5(b), hopping of electron is extremely easy to occur as compared with the case of random orientation as in FIG. 5(c).

By applying the external force to the running direction with the injection, the molecular chain can be oriented as shown in FIG. 5(b). Also, it becomes possible to reduce the distance between the molecular chains.

It is needless to say that this example can naturally be applied to formation of a predetermined area with an electrically conductive polymer also in the other examples.

By setting the orientation rate of the molecular chain in the longitudinal direction at 50% or more, movement degree of the electron is increased and the line element with more excellent characteristics can be provided. A high orientation rate can be also controlled by controlling the difference between the injection speed and the running speed. Also, it can be controlled by controlling the elongation rate in the longitudinal direction.

The orientation rate here refers to a proportion multiplied by 100 of the number of molecules having an inclination of 0 to ±5° with respect to the longitudinal direction against the total number of molecules.

By setting it at 70% or more, the line element with furthermore excellent characteristics can be obtained.

### EXAMPLE 6

In this example, the line element shown in the above example is further drawn in the longitudinal direction. The drawing method can be a technique to draw a copper wire or a copper pipe, for example.

By drawing, the diameter can be further reduced. Especially, when an electrically conductive polymer is used, the molecular chain can be made parallel in the longitudinal direction, as mentioned above. Moreover, an interval between the paralleled molecular chains can be reduced. Thus, hopping of electrons can be performed efficiently. As a result, the line element with more excellent characteristics can be obtained.

A drawing rate by drawing is preferably 10% or more. 10 to 99% is more preferable. The drawing rate is 100×(area before drawing-area after drawing)/(area before drawing).

The drawing can be repeated several times. In the case of a material with a modulus of elasticity which is not so large, it is only necessary to repeat drawing.

The outer diameter of the line element after drawing is preferably 1 mm or less. 10 μm or less is more preferable. 1 μm or less is furthermore preferable. 0.1 μm or less is the most preferable.

### EXAMPLE 7

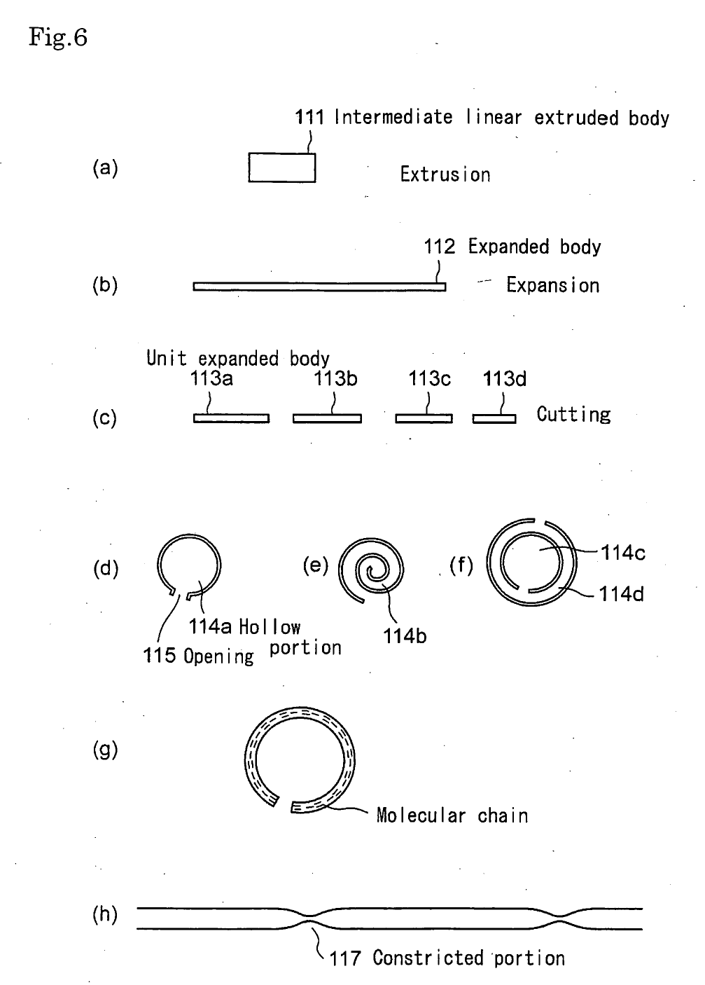

FIG. 6 shows another example.

In this example, a raw material is formed into the line state with the rectangular cross section by extrusion so as to manufacture the intermediate linear extrusion 111 (FIG. 6(a)). It can be extruded to another cross-sectional shape. Or, first extrusion can be in plural layers.

Then, the intermediate line extrusion 111 is expanded in the lateral direction in the cross section or in the cross-sectional vertical direction to form an expanded body 112 (FIG. 6(b)). In this Fig., an example of expansion in the lateral direction is shown.

Then, the expanded body 112 is cut to an appropriate number in parallel in the longitudinal direction to produce a plurality of unit expanded bodies 113a, 113b, 113c, 113d. They can move on to the next process without this cutting.

Then, the unit expanded bodies are processed in an appropriate shape. In the example shown in the Fig., they are processed to the ring shape (FIG. 6(d)), spiral shape (FIG. 6(e)), and double ring shape (FIG. 6(f)).

Then, an appropriate material is embedded in hollow parts 114a, 114b, 114c and 114d. When the unit expanded body is the semiconductor material, the electrode material is embedded. It is needless to say that embedding can be done not after processing to the ring shape but at the same time with processing to the ring shape. A material to be embedded may be selected so that a desired circuit can be formed in the relation with a material for extrusion.

Also, in the case of the double structure as shown in FIG. 6(f), different materials may be used for the unit expanded body 114c and the unit expanded body 114d.

Also, the surface can be coated by another material after extrusion (FIG. 6(a)), after expansion (FIG. 6(b) or after cutting (FIG. 6(c)). Coating may be a method like dip, deposition, plating and others, for example. A material for coating can be selected as appropriate according to the function of the element to be produced. It can be any of the semiconductor material, magnetic material, electrically conductive material or insulating material. Also, it can be either of the inorganic material or organic material.

If the electrically conductive polymer is used the expansion material in this example, the longitudinal direction of the molecular chain is oriented so that it is the right-and-left direction on the drawing which is the expansion direction. Therefore, after processing to the ring state, the longitudinal direction of the molecular chain is oriented in the circumferential direction as shown in FIG. 6(g). Thus, electrons are easy to hop in the radial direction.

Also, when processed in the ring state, if an opening 115 is provided, this opening can be used as a discharge port of electrodes or the like, for example. It can also be a connection part between line elements when an integrated device is made by weaving the line elements. Also, it can be used as a junction surface with another area.

After processed into the ring state or the like, the linear body having this ring shape or the like can be used as an intermediate body for completing the line element having the desired cross-sectional area.

As shown in FIG. 6(h), a constricted portion (a portion whose outer diameter geometry of the cross section is different from the other portions) 117 may be provided periodically or non-periodically at an appropriate position of the linear body in the longitudinal direction. When another line element is woven perpendicularly to the longitudinal direction, this constricted portion can be used as a mark for positioning. Such formation of the constricted portion can be applied not only to this example but to other line elements.

It is preferable to set the orientation rate of the molecular chain in the circumferential direction to 50% or more. It is more preferable to set it to 70% or more. By this, the line element with more excellent characteristics can be obtained.

### EXAMPLE 8

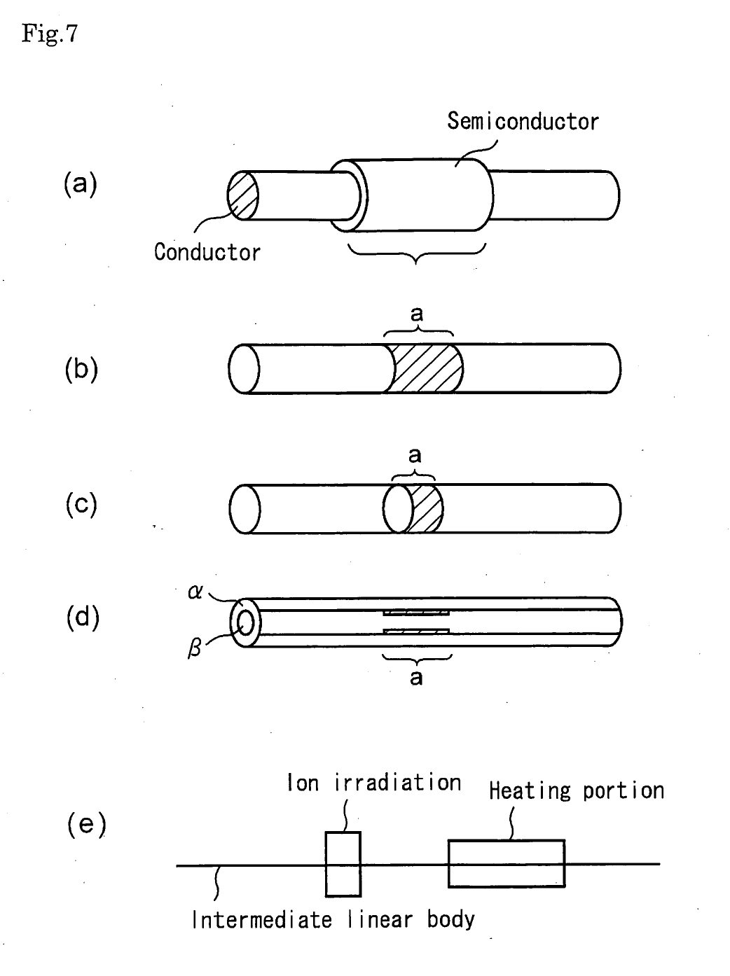

In FIG. 7, a manufacture example of the element with the cross sectional shape formed intermittently is shown.

In FIG. 7, only a part of areas forming the circuit element is shown.

FIG. 7(a) shows injection of the semiconductor material only at a timing shown by a at injection of the semiconductor material. It may be so constituted that the conductor material is injected continuously, while the semiconductor material is injected intermittently to form the conductor and the semiconductor at the same time. Also, the conductor portion may be formed in the first and then, the semiconductor material is injected intermittently around the conductor while the conductor is made to run.

In an example shown in FIG. 7(b), the line-state semiconductor or insulator is formed in the first and then, coating is implemented by intermittent deposition or the like of an electric conductor in the longitudinal direction so as to provide a portion having a different cross-sectional area in the longitudinal direction.

In an example shown in FIG. 7(c), first, an organic material is formed in the line state. Then, light is irradiated intermittently in the longitudinal direction so that photo polymerization is generated at the irradiated portion.

By this, a portion having a different cross-sectional area can be formed in the longitudinal direction.

In FIG. 7(d), α is a light-transmitting electrically conductive polymer and β is an intermediate linear body formed by integral extrusion of two layers made of a photo-hardening electrically conductive polymer. When light is irradiated intermittently while this intermediate linear body is running, light hardening occurs at a portion. By this, a portion having a different cross-sectional area in the longitudinal direction can be formed.

FIG. 7(e) is an example in which ion irradiation is used. The linear body is made to run, and an irradiating device is provided in the middle. Ion is intermittently irradiated by ion irradiation. Ion may be irradiated from all the directions or only from a predetermined direction. It can be decided as appropriate according to a cross-sectional area to be formed. Also, the ion irradiation distance may be determined as appropriate.

A heating device is provided on the downstream side of the ion irradiating device for heating the linear body after ion irradiation. An ion-irradiated portion becomes another composition by heating.

In the case of irradiation from all the directions, all the surfaces become another composition. Also, in the case of ion irradiation only from a predetermine direction, only that portion becomes another composition.

FIG. 7(e) shows an example in which the intermediate linear body to be irradiated by ion is a single-layer structure, but it is possible to implant ion only inside by controlling the irradiation distance at ion irradiation, even when it is a double-layer structure. Another composition can be formed in the irradiated inside by thermal processing.

If a silicon linear element is used as the intermediate linear body and 0 ion is implanted, a SiO₂ area can be formed. By controlling the irradiation distance, a so-called BOX (embedded oxide film) can be formed. BOX was described as the case of intermittent formation of another cross-sectional area, but the BOX can be formed over the entire area in the longitudinal direction.

### EXAMPLE 9

Application as a photoelectromotive force integrated device is possible as mentioned below.

The photoelectromotive force device can be formed by bundling, twisting or weaving the line element having the pin structure. It is preferable to constitute the pin layer by an electrically conductive polymer. Also, it is preferable to add a sensitizer.

For example, a fabric can be made by weaving the line element, and this fabric can be made into clothes. In this case, the line element as a whole becomes a light receiving area, and incident light can be received from an angle of 360°. Not only that, light can be received three-dimensionally, by which a photoelectromotive force element with excellent light receiving efficiency can be obtained.

Also, efficiency to take in light is extremely high. That is, light which was not inputted to the line element but reflected is inputted to another line element since it is taken into the fabric and reflected repeatedly. The above line element is preferably formed by extrusion.

It is only necessary to connect electrodes from each of the elements to a collecting electrode and to provide a connection terminal at this collecting electrode.

Also, by incorporating a battery in the lining of the clothes, electricity can be used in a dark place, too.

Also, by providing a heating element in the clothes, clothes having heating effect can be gained.

Moreover, by coating the line heating element with the insulating layer and weaving it in the fabric state with the line-state photoelectromotive force element, clothes with heating effect can be produced.

Also, the line element can be implanted in a board in the desired shape to have a solar battery. That is, by implanting the line element in the fluffy or erinaceous state, a solar battery with extremely high light taking-in efficiency can be obtained.

For a communication satellite, reduction of the entire weight is desired. The above solar cell is so light-weight that it is effective as a generating device in the communication satellite.

As it has flexibility, it can be formed along a desired shape and can be applied to the outer surface of the communication satellite using an adhesive.

By easily implanting the line-state photoelectromotive force element on the surface of a board conforming to the shape of a human head, an artificial wig having a power generating function can be obtained.

Also, when using a superfine line element, it can realize a leather-like surface having suede effect. Such a line element can be made into a bag. That is, a bag having a power generating function is achieved.

### INDUSTRIAL APPLICABILITY

A solar battery which is not limited by shape but has plasticity or flexibility and is capable of being formed into an optional shape and whose degree of integration is extremely high can be provided.

1. A solar battery characterized by that a plurality of line elements in which a photoelectromotive force circuit element is formed continuously or intermittently in the longitudinal direction are bundled, twisted, woven, joined, formed in combination or formed in the non-woven state.

2. A solar battery characterized by that a plurality of line elements in which a cross section having a plurality of areas forming a photoelectromotive force circuit is formed continuously or intermittently in the longitudinal direction are bundled, twisted, woven, joined, formed in combination or formed in the non-woven state.

3. A solar battery in claim 1, wherein the vertical sectional shape of the line element is a shape of circle, polygon, star, crescent, petal, letter or other optional shapes.

4. A solar battery in any of claim 1, wherein a plurality of exposed portions are provided on the side of the line of the line element.

5. A solar battery in claim 1, wherein the whole or a part of said line element is formed by extrusion.

6. A solar battery in claim 5, wherein the whole or a part of said line element is formed by extrusion and then, drawing.

7. A solar battery in claim 1, wherein said line element is extruded and then, expanded.

8. A solar battery in claim 7, wherein it is formed into the ring or spiral state after the above expansion.

9. A solar battery in claim 8, wherein said ring is a multiple ring.

10. A solar battery in claim 8, wherein said multiple ring is made of different materials.

11. A solar battery in claim 8, wherein a part of the ring or spiral is an exposed portion.

12. A solar battery in claim 8, wherein another material is filled in a part or the whole of a gap of said ring or spiral.

13. A solar battery in claim 1, wherein an outer diameter is 10 mm or less.

14. A solar battery in claim 1, wherein an outer diameter is 1 mm or less.

15. A solar battery in claim 1, wherein an outer diameter is 1 μm or less.

16. A solar battery in claim 1, wherein an aspect ratio is 10 or more.

17. A solar battery in claim 1, wherein an aspect ratio is 100 or more.

18. A solar battery in claim 1, wherein at least an area having pn junction or pin junction is formed in a cross section.

19. A solar battery in claim 1, wherein a semiconductor area forming said circuit is comprised of an organic semiconductor material.

20. A solar battery in claim 19, wherein said organic semiconductor material is polytiophene, polyphenylene.

21. A solar battery in claim 1, wherein an electrically conductive area forming said circuit is made of an electrically conductive polymer.

22. A solar battery in claim 21, wherein said electrically conductive polymer is polyacetylene, polyphenylene vinylene, polypyrrole.

23. A solar battery in claim 1, wherein different circuit elements are formed at optional positions in the longitudinal direction.

24. A solar battery in claim 1, wherein circuit element separation areas are formed at optional positions in the longitudinal direction.

25. A solar battery in claim 1, wherein different outer diameter shapes are provided at optional positions in the longitudinal direction.

26. A solar battery in any claim 1, wherein a part of an area is comprised of an electrically conductive polymer and an orientation rate in the longitudinal direction of a molecular chain is 50% or more.

27. A solar battery in claim 1, wherein a part of an area is comprised of an electrically conductive polymer and an orientation rate in the longitudinal direction of a molecular chain is 70% or more.

28. A solar battery in claim 1, wherein a part of an area is comprised of an electrically conductive polymer and an orientation rate in the circumferential direction of a molecular chain is 50% or more.

29. A solar battery in claim 1, wherein a part of an area is comprised of an electrically conductive polymer and an orientation rate in the circumferential direction of a molecular chain is 70% or more.

30. A method for manufacturing a solar battery characterized by that a material forming an area forming a photoelectromotive force circuit element is melted, fused or gelled and the material is extruded into a desired shape in the linear state to have a line element and then, a plurality of the line elements are bundled, twisted, woven, joined, formed in combination or formed in the non-woven state.

31. A method for manufacturing a solar battery in claim 30, wherein a part of said area is formed by an electrically conductive polymer.

32. A method for manufacturing a solar battery in claim 30, wherein drawing is applied after said extrusion.

33. A method for manufacturing a solar battery in claim 30, wherein expansion is applied after said extrusion.

34. A method for manufacturing a solar battery in claim 33, wherein expansion is further applied after said drawing.

35. A method for manufacturing a solar battery in claim 34, wherein formation is made into the ring state after said expansion.

36. A method for manufacturing a solar battery laminated in multiple layers from the center to the outside in claim 30, wherein a center layer is formed into filament by extrusion to have a primary filament and then, while the primary filament is running, a material of an outer layer is injected on the surface to form outer layers sequentially.

37. A method for manufacturing a solar battery in claim 35, wherein a difference between a running speed and an injection speed at extrusion of an electrically conductive polymer is 20 m/sec or more.

38. A fabric body formed by weaving a plurality of line elements in which a cross section having a plurality of areas forming a photoelectromotive circuit is formed continuously or intermittently in the longitudinal direction.

39. Clothes characterized by that being produced by weaving a plurality of line elements in which a cross section having a plurality of areas forming a photoelectromotive circuit is formed continuously or intermittently in the longitudinal direction.
